(19) United States
(12) Patent Application Publication
(10) Pub. No.: US 2015/0064365 A1
(43) Pub. Date: Mar. 5, 2015

(54) METHODS OF FORMING FILMS

(71) Applicant: SEAGATE TECHNOLOGY LLC, Cupertino, CA (US)

(72) Inventors: Philip George Pitcher, Shakopee, MN (US); Richard T. Greenlee, Hastings, MN (US); Sami C. Antrazi, Eden Prairie, MN (US)

(73) Assignee: SEAGATE TECHNOLOGY LLC, Cupertino, CA (US)

(21) Appl. No.: 14/013,320

(22) Filed: Aug. 29, 2013

(51) Int. Cl. C23C 14/12; C23C 14/48

(52) U.S. Cl. CPC C23C 14/12; C23C 14/48
USPC 427/577; 427/569

(57) ABSTRACT

A method of forming a layer, the method including providing a feedstock, the feedstock including a first component and a second component; ionizing at least part of the feedstock thereby forming a plasma, wherein the plasma includes constituents selected from: the first component, derivatives of the first component, ions of the first component, ions of derivatives of the first component, the second component, derivatives of the second component, ions of the second component, ions of derivatives of the second component, or combinations thereof, and wherein the individual identities, individual ratios, total quantities, or any combination thereof of the first and second component in the feedstock can modulate the makeup of the plasma; forming a beam from the plasma; and forming a layer from the beam, wherein the layer includes at least some portion of at least the first or the second component.

### SUMMARY

A method of forming a layer, the method including providing a feedstock, the feedstock including a first component and a second component; ionizing at least part of the feedstock thereby forming a plasma, wherein the plasma includes constituents selected from: the first component, derivatives of the first component, ions of the first component, ions of derivatives of the first component, the second component, derivatives of the second component, ions of the second component, ions of derivatives of the second component, or combinations thereof, and wherein the individual identities, individual ratios, total quantities, or any combination thereof of the first and second component in the feedstock can modulate the makeup of the plasma; forming a beam from the plasma; and forming a layer from the beam, wherein the layer includes at least some portion of at least the first or the second component.

A method of forming a layer, the method including providing a feedstock, the feedstock including a first component and a second component, and wherein the first component is from about 99.9% to about 80% of the mass flow of the total mass flow of the feedstock; ionizing at least part of the feedstock thereby forming a plasma, wherein the plasma contains constituents selected from: the first component, derivatives of the first component, ions of the first component, ions of derivatives of the first component, the second component, derivatives of the second component, ions of the second component, ions of derivatives of the second component, or combinations thereof, and wherein the individual identities, individual ratios, total quantities, or any combination thereof of the first and second component in the feedstock can modulate the makeup of the plasma; forming a beam from the plasma; and forming a layer from the beam, wherein the layer includes at least some portion of at least the first or the second component.

A method of forming a layer, the method including providing a feedstock, the feedstock containing a first component and a second component, wherein the first component is from about 99.9% to about 80% of the mass flow of the total mass flow of the feedstock, and wherein the second component is selected from noble gases, nitrogen (N₂), oxygen (O₂), hydrocarbons, hydrogen (H₂), or combinations thereof; ionizing at least part of the feedstock thereby forming a plasma, wherein the plasma comprises constituents selected from: the first component, derivatives of the first component, ions of the first component, ions of derivatives of the first component, the second component, derivatives of the second component, ions of the second component, ions of derivatives of the second component, or combinations thereof, and wherein the individual identities, individual ratios, total quantities, or any combination thereof of the first and second component in the feedstock can modulate the makeup of the plasma; forming a beam from the plasma; and forming a layer from the beam, wherein the layer includes at least some portion of at least the first or the second component.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples can be used in various combinations. In each instance, the recited list serves only as a representative group and should not be interpreted as an exclusive list.

### BRIEF DESCRIPTION OF THE FIGURES

FIG. 1 shows an example of a disclosed sub-implantation through an acetylene ion beam.

FIG. 2 illustrates how surface implantation can modulate surface density through insertion and displacement effects.

FIG. 3 shows a graph of change in stress curvature (km⁻¹) versus film thickness (Å) for the samples of Example 2.

FIG. 4 shows a graph of change in stress curvature (km⁻¹) versus film thickness (Å) for the samples of Example 3.

FIG. 5 shows a graph of the normalized change in stress curvature (km⁻¹) versus film thickness (Å) for the samples of Example 4.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

“Include,” “including,” or like terms means encompassing but not limited to, that is, including and not exclusive. It should be noted that “top” and “bottom” (or other terms like “upper” and “lower”) are utilized strictly for relative descriptions and do not imply any overall orientation of the article in which the described element is located.

Disclosed methods include steps of providing a feedstock, ionizing at least part of that feedstock to form a plasma, forming a beam from the plasma, and forming a layer from the beam. Disclosed methods control or modify the nature of the feedstock (components, relative amounts and total amount) in order to ultimately modulate the nature of layers formed therefrom. It is thought, but not relied upon, that assuming everything else (pressure, vessel, ionization type and power, temperature, etc.) is constant, adjusting the nature of the feedstock can adjust the nature of layers that are ultimately formed by modulating the makeup of the plasma.

### Providing a Feedstock

Disclosed methods include providing a feedstock. The feedstock can include at least a first component and a second component. In some embodiments, a feedstock can include one or more additional components (which can be referred to as third, fourth, etc. components). The use of first and second (and etc.) in this context is only being used for the purpose of reference, and should not be taken as implying anything about the components. The first and second components can be described by the identities of the components, the total quantities of the components, and the ratio of one component to another (or the fraction of one component to the total).

Assuming a plasma formed from a feedstock contains “constituents”, the addition of a second component into a feedstock may be used to modulate the identities of constituents, the concentrations of constituents, or combinations thereof; add new constituents to a plasma formed from that feedstock; or combinations thereof (this can be considered relative to the plasma without the addition of the second component). Since ions or ionic species are ultimately extracted from the plasma to form a beam for subsequent use in layer formation (i.e., through surface subplantation (SSP)), the addition of a second component can therefore provide a means to modulate the incident ion beam composition and thereby the effects or the layers produced by SSP. The addition of a second component may also or alternatively be able to enhance or aid in enhancing the stability of a plasma relative to the plasma without the addition of the second component. The effects of a disclosed second component can be particularly pronounced in non-mass selected beams but can also be advantageous in mass selected beams because the constituents from which the mass selected beam is being selected from can be affected.

The addition of a second component can have affects that can be in addition to, in place of, or can modulate the effect of other controls. Other controls can include, for example rf power, gas flow, source or process ambient pressure or the mode of coupling power to the source plasma, and the strength and configurations of magnetic or electrostatic fields (all of which can affect the electron energy distribution function and thereby in-part chemical reaction rates within the plasma). Even the dimensions, geometry and nature or temperature of the surfaces of the plasma source chamber (i.e., the vessel) can affect the plasma chemistry (or constituents) produced.

Furthermore, in the case of gas or vapor phase additions, even the point of introduction, whether directly into the source or indirectly, e.g., through external introduction to the vacuum environment in which the ion source is situated can have a significant influence on the SSP process and materials (films or layers) formed thereby. Direct introduction, as discussed herein can refer to introduction of the component into the source itself, whereas indirect introduction can refer to introduction of the component into the chamber in which the source is located. One method of indirect introduction is through the use of a plasma beam neutralizer (PBN) which can introduce components external to the source, but within the chamber housing the source. Another method of indirect introduction is by simply adding the component to the chamber.

### Identities of Components

The identity of the first and second components may depend at least in part on the particular layers that are to be formed using the disclosed method. For example, in some embodiments where a carbon containing layer is to be formed, a first component can include, CO, CO₂, or hydrocarbons for example. Exemplary hydrocarbons can include, for example acetylene (C₂H₂), methane (CH₄), methylacetylene (C₃H₄), ethylacetylene (C₄H₆), dimethylacetylene (C₄H₆), as well as similar compounds. In some embodiments, a first component can include acetylene (C₂H₂). In embodiments where materials other than a carbon containing layer are to be formed, different materials could be utilized as the first component.

Exemplary second components can include, for example noble gases, nitrogen (N₂), oxygen (O₂), hydrocarbons, hydrogen (H₂), or combinations thereof. Exemplary noble gases can include, for example helium (He), neon (Ne), argon (Ar), krypton (Kr), xenon (Xe), or combinations thereof. In some embodiments, argon (Ar) can be utilized as a second component. Exemplary hydrocarbons can include any hydrocarbon that is different from that utilized as a first component.

### Quantities of Components

The quantities of the first and second component can generally be described by the mass flow of the component forming the feedstock. Typically, the components (first, second, etc.) are flowed or pumped into a vessel or chamber in which the plasma is to be formed (either directly or indirectly). A component (first, second, etc.) can also be introduced as a solid. For example, the liner of the chamber can be made of material which is to be vaporized and become part of the plasma. The vessel may be kept at a relatively constant pressure, which can therefore include pumping gas (i.e., the first and second components) out of the vessel (as well as pumping the first and second components into the vessel).

In some embodiments, the quantity of a component can be described by the unit, standard cubic centimeters per minute (sccm) for example, which describes the amount of a gaseous component that is pumped into the vessel per time. One of skill in the art, having read this specification, will understand that the relevant quantity of the component will also be affected by the size of the vessel, the rate at which gas is being pumped out of the vessel, or combinations thereof. In some embodiments, components can be provided at mass flows of from <0.01 sccm to >100 sccm, depending on the above noted factors.

### Relative Quantities of Components

The relative quantities of the first and second component can be described by the ratio of one to another or by the percent of each component with respect to the total. In some embodiments, a first component can make up from 99.9% to 60% by mass flow of the total mass flow of the components making up the feedstock. In some embodiments, a first component can make up from 99.9% to 80% by mass flow of the total mass flow of the components making up the feedstock. In some embodiments, a first component can make up from 99.9% to 90% by mass flow of the total mass flow of the components making up the feedstock. In some embodiments, a first component can make up from 99.9% to 95% by mass flow of the total mass flow of the components making up the feedstock. In some embodiments, a first component can make up from 99.9% to 97% by mass flow of the total mass flow of the components making up the feedstock. In some embodiments, a second component can make up from 0.1% to 40% by mass flow of the total mass flow of the components making up the feedstock. In some embodiments, a second component can make up from 0.1% to 20% by mass flow of the total mass flow of the components making up the feedstock. In some embodiments, a first component can make up from 0.1% to 10% by mass flow of the total mass flow of the components making up the feedstock. In some embodiments, a second component can make up from 0.1% to 5% by mass flow of the total mass flow of the components making up the feedstock. In some embodiments, a second component can make up from 0.1% to 3% by mass flow of the total mass flow of the components making up the feedstock.

### Ionizing to Form a Plasma

The provided feedstock, as discussed above or some portion thereof is ionized in order to form a plasma. The plasma can be formed using known methods, systems, and/or devices. For example, the plasma can be generated using inductively coupled RF electric fields (commonly referred to as inductively coupled plasmas or ICPs), capacitively-coupled RF electric fields (commonly referred to as capacitively-coupled plasmas CCPs), ultra high frequency (UHF) electric fields (e.g., 1 to 10's GHz), or methods utilizing electron cyclotron resonance effects in conjunction with various magnetic field configurations.

The plasma generally includes some portion of the feedstock with the components of the feedstock being in some form. For the sake of clarity, a plasma will be described as containing constituents which are formed from the components of the feedstock. In general, a plasma can be described (or the constituents of a plasma can be described as) as including some combination of the feedstock, derivatives of the feedstock, ions of the feedstock, and ions of derivatives of the feedstock. Derivatives of the components of the feedstock can include fragments or combinations of a first or second component. For example, in the case of C₂H₂ (acetylene), the component itself is C₂H₂ (acetylene), derivatives thereof could include C, H, CH, CH₃, C₂H, C₂H₃, C₂H₄, C₄H₂, C₂H, as well as others; and ions of the components can include both positive and negative ions of the component itself, or any of the derivatives. It should be understood that the fragments discussed herein are exemplary only, and not all exemplified will exist, and not all will exist in the same relative amounts. As such, a plasma that was formed from a feedstock including a first and a second component could include the first component, derivatives of the first component, ions of the first component, ions of derivatives of the first component, the second component, derivatives of the second component, ions of the second component, ions of derivatives of the second component, or any combination thereof. Or stated another way, the constituents of a plasma could be described as being the first component, derivatives of the first component, ions of the first component, ions of derivatives of the first component, the second component, derivatives of the second component, ions of the second component, ions of derivatives of the second component, or any combination thereof.

The constituents of a plasma can be described by their identities as well as the flux thereof. The flux of a constituent is the number of particles/area/time. As discussed above, disclosed methods can utilize the feedstock (as well as other optional controls) to modulate the constituents (both identities and quantities) of a plasma. Modulation of a plasma can affect the identities of constituents in a plasma, the amount of one constituent with respect to another (or the total) constituent, the total quantity of constituents within a plasma, or any combination thereof. The identities of constituents in a plasma, the amount of one constituent with respect to another (or the total) constituent in a plasma, the total quantity of constituents within a plasma, or any combination thereof can be referred to here as the makeup of the plasma.

Exemplary ways in which the feedstock can affect the plasma include the following. A plasma formed from a feedstock having X sccm of a second component can have a different makeup than a plasma formed from a feedstock having Y sccm (where X is different than Y) of the same second component (even assuming all other controls remain unchanged). Alternatively, a plasma formed from a feedstock having X sccm of A second component can have a different makeup than a plasma formed from a feedstock having X sccm of B second component (where X is the same, but A and B components are different) (even assuming all other controls remain unchanged). Alternatively, a plasma formed from a feedstock having X sccm total of a first component and a second component can have a different makeup than a plasma formed from a feedstock having Y sccm total of a first component and a second component (where Y is greater or less than X) (even assuming all other controls remain unchanged). Additionally, any combinations of such differences can also form a plasma having a different makeup.

### Forming a Beam

The plasma, formed from the provided feedstock is then utilized to form a beam. Generally, a beam can be formed by extracting ions from a plasma. The ions of a plasma are utilized because the charge (either positive or negative) allows the ions to be more easily controlled (i.e., gathered and directed). Generally, a beam, because of the way in which the ions are extracted from the plasma will include either negatively charged ions or positively charged ions, but not both.

The group of ions extracted from the plasma can be used as is, or the group can be further modified or selected from. In some embodiments, ions extracted from a beam are utilized without further selection or modification. In such embodiments, the ions can have numerous forms. For example, they can include numerous different identities. In the specific case of C₂H₂ (acetylene), the ions could include C₂H₂, C, H, CH, CH₃, C₂H, C₂H₃, C₂H₄, C₄H₂, C₂H, as well as others (not all of the noted constituents need be included, and not all constituents need be included in equal amounts). Furthermore, the ions could have virtually any charge, for example in the case of a negatively charged ion beam, the ions could have −1, −2, etc. It should be noted that lower charges are generally more likely to exist in a typical plasma. The effects of disclosed methods that utilize a second component can be particularly pronounced in non-mass selected beams because a representative portion of the entire plasma is being utilized. As such, modulating the entire plasma would have a greater effect on the beam extracted therefrom.

The ions extracted from the plasma can also be further selected based on the mass thereof or the mass/charge thereof, for example. Optionally, more than one beam can be utilized, each being formed from different mass or mass/charge particles. The effects of a disclosed second component can be advantageous in beams where further selection (for example mass selection) has taken place because the constituents from which the mass (or mass/charge) selected beam is being selected from can be advantageously modulated.

### Forming a Layer

The beam, including ions extracted from the plasma, is then utilized to form a layer. A layer that is ultimately formed from a feedstock including a particular first component and a particular second component, via a plasma containing various constituents can be described as containing some part or portion of the plasma's constituents and therefore the first, or second component, in some form. It should be noted that it is not necessary that parts of both the first and second components be present in the layer that is formed. In some embodiments, only portions of the first component are desired in the layer that is to be formed. In some embodiments, only portions of the first component will be present in the layer in substantial quantities.

For example, a constituent in a beam can form part of a layer as is, can be fragmented before or while it is forming part of a layer, or can be reacted before or while it is forming part of a layer. A layer can also be described as containing at least some of the elements of the constituents of the beam that formed it in some form (either molecular or elemental) or another. For illustration purposes only, in an embodiment where a plasma includes some neutrals and ions of C₂H₂, C, H, CH, CH₃, C₂H, C₂H₃, C₂H₄, C₄H₂, and C₂H all having some charge or neutral; a beam extracted therefrom could include some of C₂H, C₂H₂ and C₂H₃ having some charge; and a layer could include carbon (C) and hydrogen (H) in some form.

“Layer” as utilized herein can refer to material on the surface of a substrate, material at the interface of the substrate (i.e. materials partially implanted into the surface but also exposed as if on the surface), material within the substrate (i.e. materials implanted into the substrate and not exposed at the surface of the substrate), or any combination thereof. Formation of a layer can therefore include implantation of the material in the bulk of the substrate (typically only to a depth of a few nanometers or less below the surface); implantation of the material at the surface of the substrate (e.g., partially embedded in the substrate); deposition of the material on the surface of the substrate (or on material that has already been formed by a disclosed method); or combinations thereof. It should also be noted that as a layer is formed, the surface is continuously moving upward away from the substrate. A “film” as utilized herein can refer to material that exists on the surface of the substrate. A layer may therefore include only a film or a film and material within the substrate. Methods disclosed herein can be utilized to form layers. The formation of layers utilizing disclosed methods can include surface modification, materials synthesis, compositional modifications, or combinations thereof. Formation of layers, as disclosed herein can include process interactions that may be confined to surface layer atoms or to within a few bond lengths from the surface. Formation of layers utilizing disclosed methods can also be referred to as surface sub-plantation (SSP).

Disclosed methods and processes may minimize or limit “undesirable effects” of layer formation to the first few atomic layers from the surface. Methods and processes disclosed herein can be described as confining the interaction of process particles (derived from the original first and/or second components in the feedstock or more specifically those being implanted, deposited, or both) with the underlying sub-surface to only a few bond lengths from the surface. The “few bond lengths” continuously moves (towards the surface) as growth proceeds. Methods and processes disclosed herein can also be characterized as controlling the exchange or coupling of energy from the process particles (those being deposited) into the surface or near surface region so that the underlying material is not detrimentally affected.

Methods and processes disclosed herein can alternatively be characterized as enabling insertion of incident species into the surface layer of atoms to within 30 Å from the surface. As used herein, incident species can include species derived from the first component, the second component, or both. In some embodiments, disclosed methods and processes can enable insertion of incident species into the surface layer of atoms to within 20 Å from the surface. In some embodiments, disclosed methods and processes can enable insertion of incident species into the surface layer of atoms to within 15 Å from the surface. In some embodiments, disclosed methods and processes can enable insertion of incident species into the surface layer of atoms to within 10 Å from the surface. The phrase “first few atomic layers from the surface” or a particular measurement (for example “within 30 Å from the surface”) from the surface are meant to refer to the top atomic layers of a near surface layer, those that are closest to the deposition/implantation surface.

Undesirable effects that can be avoided or minimized using disclosed methods and processes can include for example damage centers or more specifically displaced atoms; defect generation and recombination; vacancies and recoils; recoil mixing on a scale significant to the interface of the deposited layer with the sub-surface layer; thermal dissipation of kinetic energy from deposited ions which can anneal desired properties (for example sp3 centers in carbon containing films) from the layer; sputtering; incident particle reflection; heat generation; and implantation (and intrinsic) induced defects that can enhance thermal relaxation of localized induced strain by defect center migration which can anneal desired properties (for example sp3 centers in carbon containing layers) from the layer; and any combination thereof. Disclosed processes and methods can help control, avoid or minimize such effects, can confine them to the first few atomic layers from the surface, or both.

Disclosed methods can be utilized to engineer the composition of a layer. For example, disclosed methods can be utilized to engineer a carbon containing layer (it is noted that a carbon containing layer is utilized as an example only and compositional engineering can be undertaken with any type of material). It is also noted that compositional engineering can be utilized to form a carbon containing layer and/or a hydrogenated carbon containing layer. Application of disclosed processes or methods to the deposition of carbon containing layers can allow the sp3/sp2 ratio of the layer to be engineered. “sp3” and “sp2” refer to types of hybridized orbitals that a carbon atom (for example) may contain. An sp3 carbon atom is bonded to four other atoms, such as four other carbon atoms because it contains four sp3 orbitals, a sp3 orbital forms a very strong a bond to another carbon atom for example. An sp2 carbon atom is bonded to three other atoms, such as three other carbon atoms because it contains three sp2 orbitals, a sp2 orbital forms a it bond that is weaker than a σ bond. In numerous applications, including carbon overcoats that are used in magnetic recording heads and media, carbon having more sp3 than sp2 bonds can often be desired because the carbon is more stable (i.e., it contains stronger bonds). In some embodiments, disclosed processes or methods can allow formation of a carbon containing layer that is more stable. Such carbon layers can have higher thermal resiliency, better mechanical properties, better chemical characteristics, lower optical absorption, or combinations thereof.

Incident hyperthermal particles can penetrate the surface potential barrier through either insertion in sites between existing atoms and/or through displacing existing atoms with the production of a non-recombining recoiling atom to induce localized increase in atomic density. Local atomic reconfiguration and sp3 bond hybridization can occur to accommodate the presence of the non-equilibrium hyperthermal and displaced particles and the resulting induced localized distortion/strain. Disclosed methods can achieve this in a very thin layer contained within a few bond lengths of the surface. In addition, the energetics can be adjusted to try to minimize instantaneous recombination and the production of thermal energy which can act to annihilate or anneal out, respectively, the sp3 centers.

Some disclosed methods include processing or depositing low energy particles in order to minimize the undesired effects of implantation. The following construct can be utilized herein in order to explain the energy of the particles. In the exemplary case of a grounded beam particle source, the incident energy (V_{inc}) of a particle immediately prior to its interaction with an unbiased, uncharged substrate surface is given by the sum of the beam voltage (or screen bias), V_{b}, and the plasma potential, Vₚ, assuming the incident particle is a monoatomic, singly charged ion. In this instance, the implant energy (Vᵢₘₚ) is the same as the incident energy (V_{inc}) as described. For the case of a singly charged molecular ion or cluster, it is assumed that upon interaction with atoms at the substrate surface, molecular orbital overlap results in complete fragmentation of the molecule (or cluster) into its component atomic species. The incident kinetic energy (V_{b}+Vₚ) minus the molecular or cluster dissociation energy is then partitioned over each atomic “fragment” according to its mass fraction (mass_{atomic component}/mass_{total molecule or cluster}) of the original incident molecular or cluster mass to give Vᵢₘₚ of each fragment.

The implant energy of a particle can be selected (the maximum is selected) to restrict the ion projected range into the surface to less than a maximum of a few bond lengths. The implant energy of a particle can also be selected (the minimum is selected) to be at least sufficient to allow penetration of the surface energy barrier to allow incorporation of the particles into the surface. Because of the minimum energy selected (enough to allow penetration of the particle into the substrate), growth of the layer is not accomplished via typical nucleation growth mechanisms. The chosen range of implant particle energies being such that kinematic energy transfer to target atoms is either insufficient to produce displacement or, on average, to generally produce only one or two displacement reactions or sufficient to allow insertion into the surface or to distances within a few bond lengths from the surface.

In some embodiments, disclosed methods include utilizing particles having implant energies of tens (10s) of electron volts (eV). In some embodiments, methods include utilizing particles having implant energies of less than about 100 eV. In some embodiments, methods include utilizing particles having implant energies of not greater than about 80 eV. In some embodiments, methods include utilizing particles having implant energies of not greater than about 60 eV. In some embodiments, methods include utilizing particles having implant energies of not greater than about 40 eV. In some embodiments, methods include utilizing particles having implant energies of not greater than about 20 eV. In some embodiments, methods include utilizing particles having implant energies from about 20 eV to about 100 eV. In some embodiments, methods include utilizing particles having implant energies from about 20 eV to about 80 eV. In some embodiments, methods include utilizing particles having implant energies from about 20 eV to about 60 eV. In some embodiments, methods include utilizing particles having implant energies from about 20 eV to about 40 eV.

At the disclosed low implant energies further complications can exist with the practical implementation of disclosed methods because of the interaction of the low implant energy particle cross-section with multiple rather than single surface atoms resulting in complex, indeterminate many body collision kinematics and enhanced defect recombination rates through low kinematic energy exchange (which may act to reduce sp3 center generation).

Techniques for the production of highly controlled particle beams are well developed for the ion implantation and etch technologies (KeV energy range) and in the sputter deposition or evaporation deposition regime (<about 15 eV). In contrast, technology is much less developed for energies of approximately tens of electron volts (eV) which are of interest in disclosed methods. At these energies, technological constraints can result principally through space-charge interactions between ions in the beam. These effects can limit the generation of practicable beam currents (densities) and the quality of the beam ion-optical characteristics that can be important in, for example, focusing and mass selection. Generally, the required beam characteristics at energies of only a few tens of eV are outside the operational envelopes of broad beam ion sources, the mainstay of many conventional dry processing techniques.

Disclosed methods and systems enable application of commercially proven ion source technology to the low energy methods disclosed herein. The use of molecular ions in low energy ion beam processing techniques allows processing at energies within the ion energy design operation envelope of the ion gun at sufficient energies to allow usable beam currents. By partitioning the incident ions kinetic energy on a molecular ion it is possible to implant or sub-implant at lower implant energies than the incident ion energy, these energies not normally practically accessible with typical ion gun physics. The implant molecular or cluster ion energy is selected to be sufficient to overcome barriers to low energy sub-implantation or surface processing e.g. ion reflection and/or surface potential barrier effects (as discussed above). As the incident particle approaches a substrate atom, instantaneous molecular or cluster fragmentation occurs as electron orbitals overlap, resulting in partitioning of the incident ion energy amongst the implanting/sub-implanting particle fragments (which can also be referred to herein as “component atomic species”). Appropriate selection of molecular ion species and incident energy allows proper engineering of the implant energy of the fragments to the desired energy for surface sub-plantation (SSP).

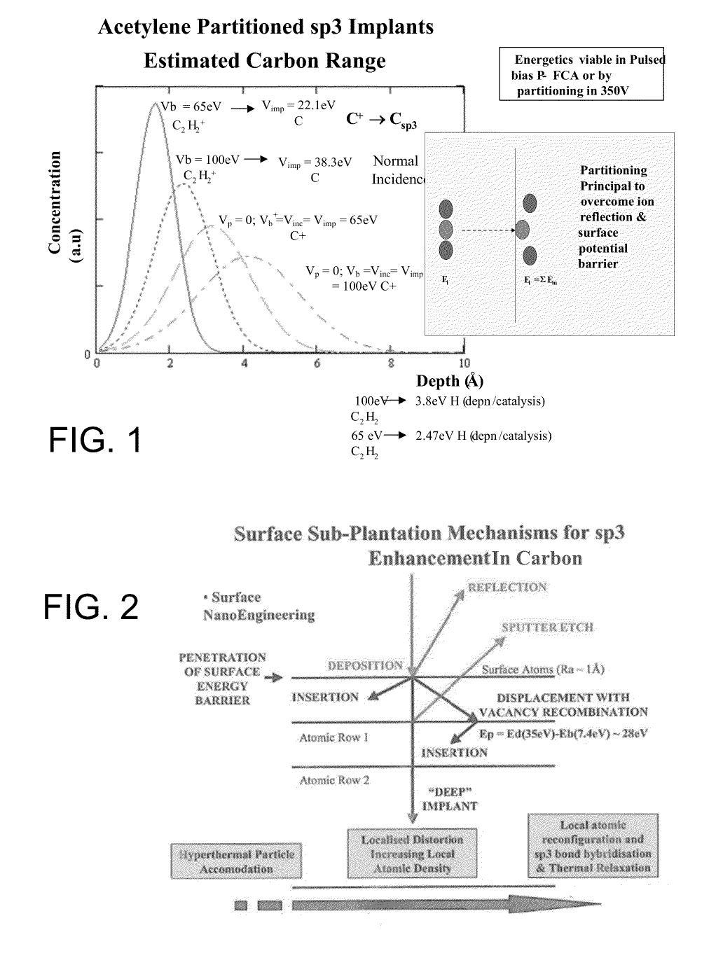

FIG. 1 compares the estimated carbon range (depth into the substrate) of both acetylene partitioned particles and carbon (non-partitioned) particles. FIG. 1 shows that partitioning of the ion energy upon fragmentation decreases the depth of interaction of the deposited species. Specifically, FIG. 1 shows that fragments from polyatomic species (C₂H₂⁺ in the example shown in FIG. 1) do not interact as deeply into the surface as ions directly formed from an ion beam (C⁺ in the example shown in FIG. 1). The energetics depicted in this example are viable in a pulsed bias P-FCA or by partitioning in a gridded or gridless ion source. Note that through suitable control of the incident molecular ion energy, the secondary ion fragments, hydrogen in the case of FIG. 1, may or may not be incorporated into the growing layer. In the embodiment depicted in FIG. 1, the hydrogen would likely not be incorporated into the layer because the energies are not high enough (3.8 eV and 2.47 eV) to allow the hydrogen particles to enter the substrate. Although, chemical effects may provide a mechanism for incorporation of such hydrogen particles. Use of a second component, as described herein may offer methods of tailoring such chemical effects. In some disclosed embodiments, suitable control of the ion beam current density may be exercised to control the defect introduction rate.

In molecular ion energy partitioning, particularly with non-mass selected ion sources, limitations exist on the ability to control the nature of the incident species and therefore the kinematic processes. Such kinematic processes can be important in achieving new nanoengineering methodologies in nanomaterials synthesis, etch, interfacial nanoengineering, nanodoping and metastable surfaces (principally through the fragmentation process). These effects may limit, for example, the conversion efficiency of sp3 centers and therefore thermo-chemo-mechanical robustness that may be relevant to certain applications (for example heat assisted media recording (HAMR) or perpendicular overcoats). There is often a delicate balance in surface nanoengineering between process threshold effects, the available nanoprocessing window and competition from process disruptive elements. Indications of SSP process thresholds were given above in terms of molecular orbital interaction effects and kinematic thresholds for sp3 center formation. Phonons, produced through the kinematic process of sp3 center formation, act to annihilate sp3 centers by reducing localized strain excursions by thermal migration of atoms. Comparing the threshold energetics for sp3 center synthesis with an estimate of ion induced carbon atom jumps induced as a function of incident ion energy below clearly indicate the importance of process control in surface nano-engineering technology. Reducing substrate temperature during the deposition process may significantly affect the ratio of sp3/sp2 centers produced by the SSP process.

Alternative approaches to low energy processes, include substrate biasing (including high frequency biasing and pulsing), filtered cathodic arc (FCA) deposition techniques and altering the source potential in either ion beam deposition (IBD) or FCA techniques. Such approaches can be used singly or in combination. However, in all these techniques although some critical process elements may be easily controlled (for example, energy), typically, other key process control parameters for surface nanoengineering processes (for example the incident arrival angle spectrum) are not. Application may be best carried out with conductors, and stray field effects can limit the degree of control.

Also disclosed herein are optional methods and/or steps to improve low energy processing techniques utilizing the acceleration and/or deceleration of ions, which are referred to herein as “ion accel-decel” approaches. Such ion accel-decel approaches can be accomplished with mass selection, beam conditioning and shaping in conjunction with goniokinematic processing (coordinated real time variation of particle beam parameters with the goniometric (angle) disposition of the target process surface (with respect to the beam axis)) to control factors that afford control of process phenomena, for example etch, interfacial nanoengineering, nanodoping, surface nanoengineering of nanomaterials and metastable surface materials. Ion accel-decel approaches can circumvent low energy ion beam transport effects and poor ion source performance characteristics at low energies (e.g. impractically low beam currents) to improve process control. Ions can be accelerated and conditioned at high energies and then decelerated to impact energy just prior to collision with a substrate. The existence limits for low energy processes can, however, be extremely narrow and easily corrupted.

In low energy, low beam current density processes, massive beam divergence can be exhibited by the beam (with probable loss of process control) if proper consideration of the “throw” distance to the substrate table is not made in instrument design together with proper control of deposition rate in the process window. Process control of particle energy, beam current, beam divergence, charge state and ion mass are typically static in conventional process techniques. However variation of selected beam parameters may be used to e.g. tailor interfaces, compositional or damage center concentration profiles with and without sample goniometric motions. In conjunction, variably doped multilayer nanostructures or selective depth or surface doping may be achieved by appropriate switching of the mass filter parameters during or post-film growth e.g. in lube engineering applications.

An advantageous use of a controlled low energy, mass filtered, collimated beam particle source with beam current control is in goniokinematic physicochemical processing techniques. These methods may prove pivotal in driving surface collisional processes to enable controlled nanoengineering of surfaces, interfaces and near surface regions. Goniokinematic processes require coordinated real time variation of particle beam parameters with the goniometric disposition of the target process surface (with respect to the beam axis). Such methods can for example help selectively control whether incident particles interrogate surface or sub-surface atoms and thereby interact with target atoms or chains of atoms through a surface interatomic potential or internal “bulk” interatomic potential or both. This in turn may determine the probability of achieving a desired surface collision or surface collision sequence or overcoming a potential barrier to a surface reaction. A particular profile of incident particle energies correlated to a select value or range of impact angles may be used for these purposes or to control a depth profile of implanted atoms e.g. in a doping concentration profile.

Narrow ion beams are typically electrostatically scanned over a substrate surface to produce a uniform ion dose. This can result in position variable angular registration of incoming ions with target atoms and therefore variations in collision kinematics, even for a fixed substrate position. Furthermore, beam scanning can produce positional incident energy variation and positionally variable beam current densities even for fixed values of beam energy and beam ion current at the ion source on static substrates. Mechanical scanning techniques combined with beam shaping methods can ameliorate several potential goniokinematic process variation effects created by electrostatic scanning of spot particle beams. Examples include a particle beam formed into a thin “slot” like profile of uniform intensity and a substrate scanned in a vertical or horizontal axis with respect to the beam axis to achieve overall uniform illumination over the substrate area. Some scan systems may use a static slot beam profile combined with a high speed rotation of the substrate in conjunction with a slower lateral or longitudinal scan motion to achieve a uniform field of particle irradiation over the substrate area. Such techniques can allow constant incident areal particle density processing over the substrate field in contrast to beam scanning techniques even if the substrate is tilted. In low energy nano-engineering ion beam processing the variation in length of field free drift path (FFDP) produced by beam scanning alters not just the particle incidence angle but also could cause considerable alteration to the incidence beam divergence affecting critical goniokinematic process variables which are also inconsistent across the materials process plane. This is further compounded by a positionally variable areal particle density. Static, shaped, particle beams with substrate motion can be designed to allow goniometrically variable processing of the substrate at constant FFDP and incident particle areal density.

Methods disclosed herein can generally be referred to as surface sub-plantation (SSP). Such SSP methods can include processes and steps that enable insertion of incident species into a surface layer of atoms to within only about 30 Å from the surface. Disclosed methods are novel and advantageous because they do not interact with atoms that are deeper into the surface, for example they do not interact or do not appreciably interact with atoms that are deeper than about 30 Å into the surface. In some embodiments, disclosed methods are novel and advantageous because they do not interact or do not appreciably interact with atoms that are deeper than about 20 Å into the surface. In some embodiments, disclosed methods are novel and advantageous because they do not interact or do not appreciably interact with atoms that are deeper than about 15 Å into the surface. In some embodiments, disclosed methods are novel and advantageous because they do not interact or do not appreciably interact with atoms that are deeper than about 10 Å into the surface.

Disclosed methods can be utilized to form layers of any material; or stated another way incident species that are inserted into a surface layer can have any identity or identities. In some embodiments, disclosed methods can be utilized to form layers that include carbon. In some embodiments, disclosed methods can be utilized to form layers that include carbon as a hydrocarbon (e.g., hydrogenated carbon). It should be understood however that carbon and hydrocarbons are simply an example and disclosed methods are not limited to formation of carbon and/or hydrocarbon layers or films.

Disclosed methods strive to confine the processing effects to the top few bond lengths of the layer continuously, as growth proceeds. This can minimize or eliminate the effects of non-linear atomic interaction of implanting particles with substrate atoms (which may still be present when the angle of incidence is merely changed). FIG. 2 illustrates how surface implantation can modulate surface density through insertion and displacement effects. In some embodiments where a film including carbon is being formed, this can also modulate sp3 bond hybridization.

As seen in FIG. 2, surface implantation can be complicated by several mechanisms, including sputter etching, penetration of the surface energy barrier and ion reflection. A process energy window can be estimated from calculation estimates of these effects. For the case of a carbon implanted in a carbon or hydrocarbon substrate surface, size effects effectively determine the minimum energy for penetration; this is estimated from estimates of collision cross-sections to be about 20 to 25 eV. This is close to typical atomic displacement energies that correspond to the high energy tail of ion beam deposition (IBD) sputter deposition techniques. From a study of possible surface atom ejection mechanisms, a maximum arrival energy, for example from normal incidence, can be calculated to avoid excessive sputtering of the growing film and compared to predictions based on the energy dependence of the sputter coefficient. Sputtering, in part defines the upper energy limit (in certain embodiments) for the surface sub-plantation (SSP) technique. Both models predict minimal atomic ejection below about 40 to 42 eV. Practically, predictions from the energy dependence of the sputter yield indicate only about 10% surface sputter loss at about 60 eV, setting an effective “zero” sputter loss estimate for the upper process limit in some embodiments. In other embodiments, greater sputter losses may be tolerated or even desired, e.g., approximately 30-40% at implant energies of 80 eV in this example. It should be noted that the specific values discussed above apply onto the case of carbon; however the considerations apply to implantation of any material.

In some embodiments, low implant energy particles can be formed from a broad beam ion source, or a narrow beam ion source for example. A specific example of a source of particles is an inductively coupled RF, gridded ion source. A source of particles is referred to herein as a particle beam.

Disclosed methods can also utilize beams that are directed towards the surface of a substrate (upon which a layer is to be formed) at a particular angle or particular angles of incidence. The angle of incidence of the particle beam can be characterized with respect to the substrate. More specifically, the angle of incidence of the particle beam can be characterized with respect to the substrate or surface normal. As such, the angle of incidence of the particle beam can be described by the angle of the particle beam relative to the surface normal. For example, a particle beam that is directly perpendicular to the surface of the substrate, would be characterized herein as having an angle of 0° with respect to the surface normal. A particle beam that is directly parallel to the surface of the substrate, would be characterized herein as having an angle of 90° with respect to the surface normal. In some embodiments, the angle of incidence can be less than 90°, in some embodiments less than 80°, and in certain embodiments, less than 70°. Generally, as the angle of incidence of the beam (relative to the surface normal) increases, the depth that the incident species reach into the film (or layer) decreases.

Disclosed methods can also implant incident species at more than one angle of incidence in order to control and manipulate the distribution of implanted atoms. For example, a series of angles of incidence (which produce different angular depth profiles) can be superimposed in order to obtain a final desired composite depth profile. The depth limits of the distribution can be set through upper and lower angular limits of a sequential differential scan. In some embodiments, the angle of incidence can be scanned from 90° to 0°. In some embodiments, the conditions for producing a thin lamella, thickness Δx, of uniform concentration (C₀) of implanted atoms can be approximated by incrementally angularly separated processing. The angular profiles are separated by an incremental angle Δφ for a given ion-material, energy and concentration combination. By appropriate variation of the dwell time at each angle (separated by the incremental angle) the goniometric flux variation and goniometric ion range variation can be accommodated to produce a linear concentration depth profile. The “integrated” profile is almost independent of the process inherent angular concentration profile, excepting a small “error” due to range straggle. In fact, the incremental angle and dwell technique can be extended to produce a depth profile of almost any shape at a controlled depth location.

Disclosed methods may also include a step of changing the angle of incidence of the particle beam, the energy of the particles, or a combination thereof. Once the angle, the energy or the combination is changed, the particle beam is directed towards the surface again in order to implant incident species again. The steps of changing the angle, the particle's energy, or combination thereof and implanting particles again can be repeated a plurality of times or may be continuously variable.

In some embodiments, the angle can be scanned (either constantly or variably—in terms of time at a particular angle or distance between the angles, or both) from a minimum (e.g., 0°) to a maximum (e.g., 90°) using chosen dwell times and chosen increments. In certain embodiments, disclosed methods can also include changing the angle of incidence, energy of the particles, or a combination thereof a plurality of times; for example by scanning. The angle of incidence, the range of the angle of incidence, (α₁−αₓ), the incremental change in the angle of incidence (Δα), the time at each setting (t₁−tₓ), the energy of the particles, or any combination thereof can be chosen to produce a desired concentration depth profile (for example a linear concentration depth profile) of the material in the film.

The substrate upon which the layer is to be formed can be any type of material or structure. In some embodiments, an exemplary substrate can have at least one surface upon which the layer formation will take place. Such a surface can be referred to as “being adapted for layer formation”, which can include simply being placed in a process chamber so that a layer will be formed on at least the desired surface. In some embodiments, the substrate can include structures or devices formed thereon or therein. In certain embodiments, methods disclosed herein can be utilized to form overcoats on various structures; and in such embodiments, the device upon which the overcoat is to be formed can be considered the substrate.

Various processes and procedures can optionally be carried out on the substrate before a layer is formed thereon. In certain embodiments, the surface of the substrate can be etched before a layer is formed thereon. A specific example of a pre-layer formation etch can include the following: a beam voltage (V_{b}) of about 300V; a beam current (I_{b}) of about 300 mA; 15 sccm Ar@40-80° incidence angles (e.g dual angles) from normal. Typically 10-100 Å can be removed by a single etch or multiple etches that may include changes to the energy, beam current, incident angle, gas composition variation, pulsed operation. The same source that is to be used for formation of the layer may be used or alternatively a separate source in either the same or a separate chamber may be used.

Disclosed methods can also include a step of directing a particle beam towards the surface of a substrate. The particle beam includes particles, which can also be referred to herein as incident species (once they strike the surface). The particles are generally low impact energy particles. In some embodiments, the beam can include species derived from the primary component or species derived from the primary component and the secondary component. The particles can either be monoatomic or polyatomic. Monoatomic particles have impact energies that are the same as their incident energies. Polyatomic particles on the other hand will have impact energies that are different than their incident energies. The impact energies of the component atomic species of a polyatomic particle will be less than the incident energy of the polyatomic particle. For the case of a singly charged polyatomic particle it is assumed that upon interaction with the substrate or surface atoms, molecular orbital overlap results in complete fragmentation of the polyatomic particle into its component atomic species. The incident energy (V_{inc}, which equals V_{b}+Vₚ) minus the molecular dissociation energy is then partitioned over each component atomic species, or “fragment” according to its mass fraction of the original incident molecular mass. Exemplary impact energies and ranges thereof were discussed above.

Disclosed methods form layers. As discussed above, a layer can refer to material on the surface of a substrate, material at the interface of the substrate (i.e. materials partially implanted into the surface but also exposed as if on the surface), material within the substrate (i.e. materials implanted into the substrate and not exposed at the surface of the substrate), or any combination thereof. In embodiments, methods disclosed herein do not form layers based on nucleation growth mechanisms. Nucleation growth mechanisms fundamentally limit the minimum thickness of a continuous film.

Disclosed methods can change the fundamental growth mechanism from nucleation, which relies on surface mobility effects. Nucleation based methods are typical in processes that utilize incident energies that are less than about 20 eV (e.g., typical sputter deposition methods are from about 7 to about 15 eV; and evaporation methods are less than about 1 eV). Disclosed methods suppress mobility by implantation into a near surface region. The implanted region is kept shallow in order to produce ultrathin altered surface regions. To accomplish this, low energy incident particles, which are difficult in practice to produce at usable beam fluxes, are utilized. Conventional low energy implantation still utilizes particles having (10's-100s) KeV energies in order to achieve commercially viable beam currents. The particles utilized are relatively large molecules or clusters so that the fragments have low energies; e.g., in silicon doping. For functional engineering of nm scale films, this fragmentation process does not allow sufficient control. Disclosed methods therefore utilize very low incident energies with partitioning over small molecules to achieve controllable, very low implant energy particles.

At least some of the material making up the particle beam will be part of the material of the layer to be formed. In some embodiments, materials from the particle beam will be inserted into a substrate, in which case a mixture of the material from the particle beam and the substrate material will be formed. In some embodiments, layers containing carbon (for example) are formed. In some other embodiments, layers containing hydrogenated carbon (both carbon and hydrogen) are formed. Layers that are formed can have various thicknesses. The thickness of a layer, as that phrase is utilized herein, refers to a measure of the thickness. For example, a measure of a thickness may provide an average thickness, or may provide a property that can be related to the thickness or the average thickness of the layer. For example, layers can be from about sub-monolayer (less than a monolayer of the material) to about 30 Å thick. In some embodiments layers can be from about 15 Å to about 25 Å thick; and in some embodiments, layers can be from about 15 Å to about 20 Å thick.

Commonly utilized film fabrication processes and methods typically aren't carried out at energies as low as about 20 to 100 eV. Methods have therefore been developed to process, using standard film fabrication equipment, at energies as low as about 20 to 100 eV. Filtered cathodic arc (FCA) equipment may be capable of operating at these low energies by raising the plasma potential in the FCA arc source. This can be accomplished by biasing the electrode of the FCA, biasing the substrate to be deposited on, or a combination thereof. In some embodiments, a high frequency, pulsed substrate biasing technique with a controlled duty cycle may allow the formation and collapse of the substrate plasma sheath, which could minimize substrate charging effects which can occur for insulated, floating or negatively biased substrates.

Disclosed methods can include various steps, including for example: providing a substrate having at least one surface adapted for deposition thereon; and depositing particles from a deposition beam onto the surface of the substrate, wherein the deposition beam has an elevated plasma potential. Any method of forming a deposition beam with an elevated plasma potential can be utilized. As discussed above, the plasma potential can be elevated by biasing the electrode of the deposition beam (for example the anode in an FCA source or if present in a gridded ion beam source), biasing the substrate to be deposited on, or a combination thereof.

In some embodiments, where the electrode of the deposition beam can be biased, the electrode can be biased, which can also be referred to as the beam voltage, V_{b}, from about 0 V to 210 V, for the case of acetylene incident ions. In some embodiments where the substrate is biased, the substrate can be biased from about 0 V to 210 V. In some embodiments, a high frequency, pulsed bias can be utilized. For example, a frequency less than about 40 KHz can be utilized, and in some embodiments a frequency of about 25 KHz. The duty cycle can be from 0 to 100%.

Another method of providing particles at implant energies from about 20 eV to about 100 eV includes the use of molecular ions. By partitioning incident ions' (for example from a ion gun) kinetic energy onto a molecular ion, it can be possible to implant or sub-implant at lower energies than the incident ion energy. Because the implanting particle does not receive all of the energy of the incident molecular ion (some energy is lost in the ion fragmentation and energy partitioning according to its mass fraction of the total molecular mass), the energy of the implanting particle is less than that of the incident ion. The final energy of the molecular ion then is designed to be sufficient to overcome the barriers to low energy sub-implantation, for example ion reflection and/or surface potential barrier effects. Upon sufficiently close proximity, instantaneous molecular or cluster fragmentation through electron orbital overlap with surface atoms results in partition of the incident ion energy amongst the implanting/sub-implanting ion fragments.

Partitioning incident ions' kinetic energy onto molecular ions can include monoatomic molecular ions or polyatomic molecular ions. These monoatomic or polyatomic molecular ions can then interact with the surface and be deposited in order to form films.

An example of sub-implantation through an acetylene ion beam is shown in FIG. 1. FIG. 1 shows that deposition by partitioning of the ion energy upon fragmentation decreases the depth of interaction of the deposited species. Specifically, FIG. 1 shows that monoionic species (C₂H₂⁺ in the example shown in FIG. 1) do not interact as deeply into the surface as ions directly formed from the ion beam (C⁺ in the example shown in FIG. 1). The energetics depicted in this example are viable by molecular partitioning for example in an ion beam deposition and etching tool. Note that through suitable control of the incident molecular ion energy, the secondary ion fragments, hydrogen in the case of FIG. 1, may or may not be incorporated into the growing film structure. In some disclosed embodiments, suitable control of the ion beam current density as well as energy may be exercised to control the defect introduction rate.

Methods that utilize molecular ions can also include steps of directing an ion beam (for example from an ion gun) at the surface of the substrate. The ion beam can generally include ions having energies from about 5 eV to about 200 eV. Typically utilized and commercially available ion sources (both narrow beam and broad beam) can be utilized. The ions in the ion beam transfer or partition a portion of their energy to the component atomic species upon fragmentation at the substrate. The energized species then forms a layer on or imbedded in (or a combination thereof) the substrate by implanting into the first few atomic layers of the substrate (or film).

The molecular ions that implant into the surface can, in some embodiments, include carbon atoms (a specific example of a molecular ion includes C₂H₂⁺). Molecular ions are by definition, polyatomic, e.g., they include more than one atom (e.g., C₂H₂⁺). The energy, at incidence of a molecular ion (or an incident species) can be from about 20 eV to about 250 eV; or from about 20 eV to about 150 eV; or from about 20 eV to 100 eV; or from about 20 eV to about 70 eV. Exemplary polyatomic ions can include hydrocarbons. In some embodiments, exemplary hydrocarbon containing polyatomic ions can include less than six carbons for example; and in some embodiments four or less carbons.

Gases other than the primary component and secondary component may also be introduced into a particle source or chamber in exemplary methods. In some embodiments additional gases can be introduced in order to carry out a simultaneous etch-deposition process. The additional gases may be introduced indirectly or directly into the process. The function of the additional gas or gases may be to augment a pure gas SSP process or to provide a controlled etch rate capability where the etch rate is less than the rate of formation of the film. An etch gas may be indirectly introduced, for example from a beam neutralizer (for example a Plasma Bridge Neutralizer (PBN)) or directly into the background of the chamber, or through direct introduction into the ion source. In some embodiments, indirect introduction is favored. In some embodiments, gases that are introduced to etch can be introduced at rates less than about 15 sccm; and in some embodiments at rates of about 1 to about 3 sccm (for the example of a 30 cm diameter ICP broad beam ion source).

Disclosed methods can also be combined with other methods of forming films and devices formed thereby. An exemplary, but non-exhaustive list of United States patent applications containing related methods includes commonly assigned U.S. patent application Ser. Nos. 13/440,068; 13/440,071; 13/440,073; 13/756,669; 13/798,469 13/923,922; and 13/923,925, the disclosures of which are incorporated herein by reference thereto.

### EXAMPLES

### Example 1

### Exemplary Process Flow

In this example, an inductively coupled RF, gridded ion source (30 cm diameter) was utilized. The process chambers are typically pumped to <10⁻⁶ torr.

The source pre-condition may have operation settings for plasmas formed from inert gas and oxygen or inert gas mixtures individually or sequentially. For example, V_{b}=500V, I_{b}=300 mA with sequential gas mixtures: 10 sccmAr+5 sccm O₂, 15 sccm O₂, 10 sccmAr+5 sccm O₂, 15 sccm Ar with variable durations typically less than 10 mins (for example 3-5 mins at each stage).

The substrate may be obscured by a mechanical shutter or ion gun electronic shutter or rotated such that it is not exposed to any flux from the ion source(s) at any stage prior to pre-deposition etch and deposition stage.

The ion source ignition was done using an inert gas, for example Argon.

A pre-etch stabilization can be carried out by setting the operational parameters to etch conditions. Typically this was an inert gas etch but is not restricted to inert gases. For example V_{b}=300V, I_{b}=500 mA, 15 sccm Ar for 3 mins. The same source that is to be used for surface modifications may be used or a separate source in either the same or a separate chamber may be used.

A pre-layer formation etch can be carried out. It is typically done in an inert gas, but is not limited to inert gases. For example, V_{b}=300V, I_{b}=300 mA, 15 sccm Ar@40-80 deg incidence angles (e.g dual angles) from normal. Typically 10-100 Å was removed by a single etch or multiple etches that may include energy, beam current, incident angle, gas composition variation pulsed operation. The same source that is to be used for surface modifications may be used or a separate source in either the same or a separate chamber may be used.

A pre-layer formation source stabilization may also be carried out. This includes a sequence of gas changes from an inert gas to an inert gas plus a hydrocarbon mixture to a final pure hydrocarbon plasma or hydrocarbon plus minority additions of other gases (for example inert gases, other hydrocarbons, or other molecular species containing carbon). The final ion source settings are at low beam voltage and beam current, which are close to, or at deposition values. A plasma bridge neutralizer (PBN) or other beam neutralization device may (or may not) be turned off during the final stage of source stabilization. This is typically a three stage process, but it can be more or less than 3 stages. For example V_{b}=200V, I_{b}=100 mA, PBN 2 sccm Ar, Electron Emission current of 200 mA @10 sccmAr+10 sccm C₂H₂, then 5 sccmAr+25 sccm C₂H₂ for 3 mins each stage, no PBN 30 sccm C₂H₂ 5 mins.

The next step in this exemplary method is the actual surface sub-plantation (SSP) step. For a 30 cm ion source with Acetylene (C₂H₂) plasma support gas @5-60 sccm gas, typically 25-30 sccm, are pumped to provide a process pressure in the range of 10⁻²-10⁻⁴ torr. The beam voltage is typically 70<V_{b}<180 V (for example 71 or 126V) and the beam current I_{b}<200 mA (for example 65 mA). The deposition angle is typically normal incidence but may be up to <80 degrees from the substrate surface normal. Typical throw distance is 12″ at normal incidence. Parallel grids were used throughout. The PBN neutralizer may be off or on at this stage.

Additional gases may be indirectly or directly introduced to the process. Their function may be to augment a pure gas SSP process or provide a controlled etch rate capability where the etch rate is <rate of formation of modified surface or film. An etch gas may be indirectly introduced from a beam neutralizer (for example a PBN) or through direct introduction into the ion source. In some examples, indirect introduction is utilized, the gases are inert gases introduced at <15 sccm e.g 1-3 sccm.

Continuous operation of a deposition process would only require the steps prior to surface subplantation (for example, source pre-condition, ion source ignition, pre-etch stabilization, prelayer formation etch, and pre-layer formation source stabilization) periodically as a maintenance procedure (assuming the use of a secondary etch source).

### Example 2

### Effect of the Addition of a Secondary Component

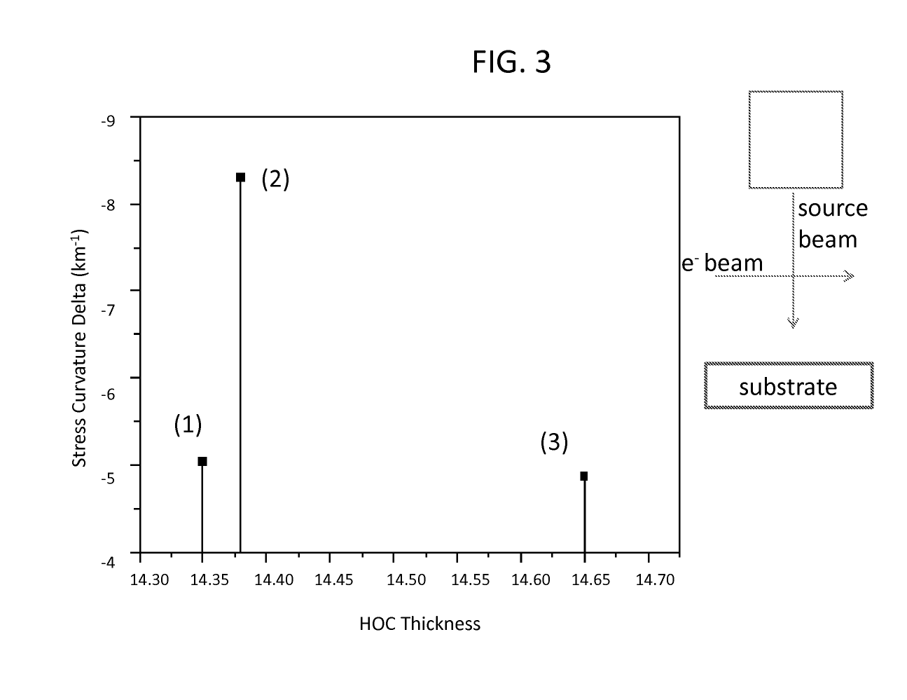

Layers were produced by the acetylene surface sub-plantation method described in Example 1 above with the addition of a secondary component (and no secondary component for the sake of comparison). FIG. 3 shows the change in stress curvature (km⁻¹) as function of the thickness of the sample (Å) for a sample formed as described in Example 1 above (sample 1 in FIG. 3); for a sample formed as described in Example 1 above except that 2 sccm Ar was introduced in the chamber via the PBN (chamber background) (sample 2 in FIG. 3); and for a sample formed using an electron cross beam process (sample 3 in FIG. 3). The schematic in FIG. 3 demonstrates the configuration of the electron beam and the source beam with respect to the substrate.

The Weibull characteristics (RWTTF lifetime) were also determined for samples 1 and 2. Sample 1 had a Weibull value of 3324 seconds and Sample 2 had a Weibull value of 6873.

### Example 3

### Effect of Indirect Versus Direct Introduction of Secondary Component

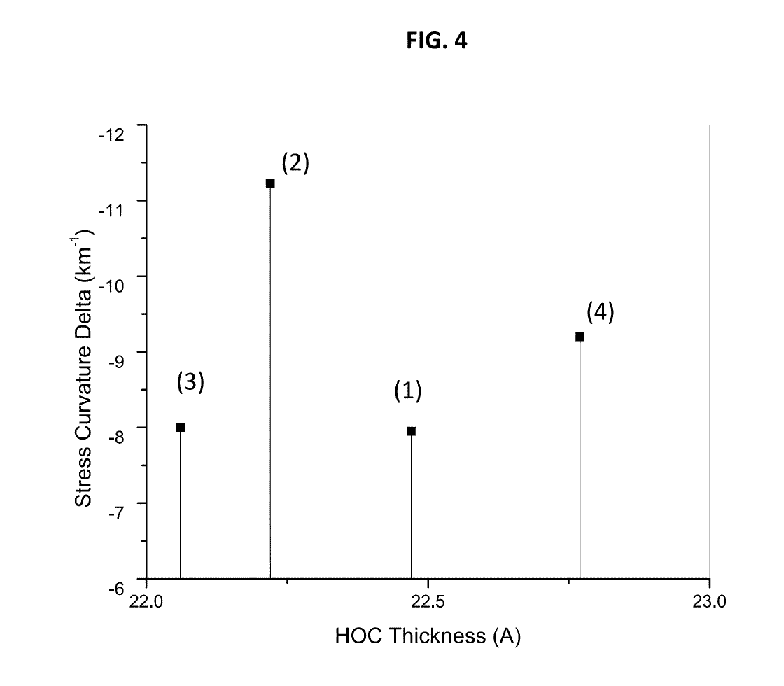

Layers were produced by the acetylene surface sub-plantation method described in Example 1 above by introducing a secondary component indirectly and directly. FIG. 4 shows the change in stress curvature (km⁻¹) as function of the thickness of the sample (Å) for a sample without a secondary component (sample 1 in FIG. 4), with introduction of 2 sccm Ar in the chamber via the PBN (chamber background) (sample 2 in FIG. 4), with a sample using an electron cross beam process (sample 3 in FIG. 4), and with introduction of an equivalent (2 sccm) flow of Ar via a direct source gas addition (sample 4 in FIG. 4).

### Example 4

### Effect of the Flow Rate of a Secondary Component

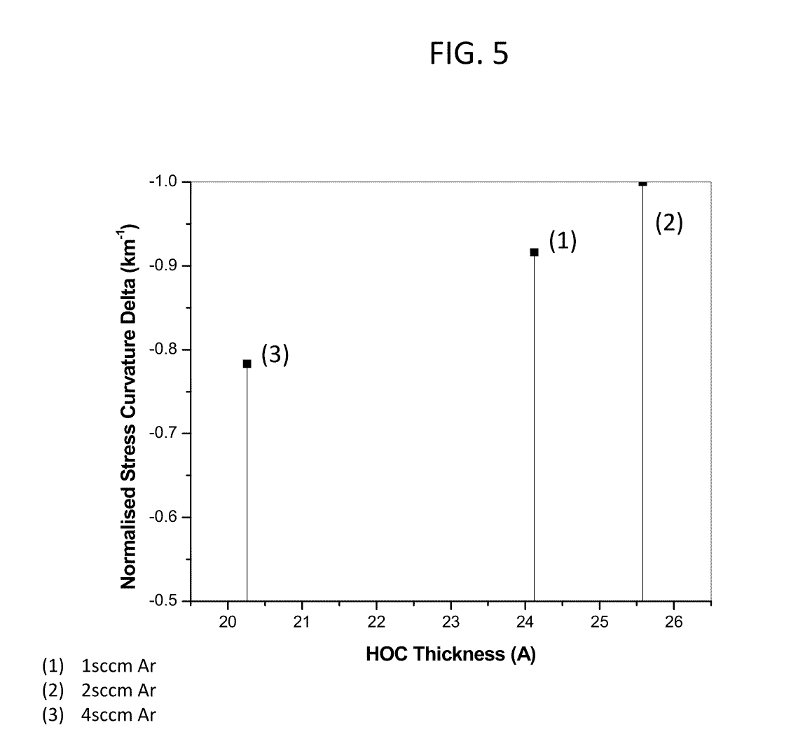

Layers were produced by the acetylene surface sub-plantation method described in Example 1 above with indirect addition of a secondary component at various flow rates. FIG. 5 shows the change in stress curvature (km⁻¹) as function of the thickness of the sample (Å) for a sample formed as described in Example 1 above except that 1 sccm Ar was introduced in the chamber via the PBN (chamber background) (sample 1 in FIG. 5), 2 sccm Ar was introduced in the chamber via the PBN (chamber background) (sample 2 in FIG. 5), and 3 sccm Ar was introduced in the chamber via the PBN (chamber background) (sample 3 in FIG. 5).

Thus, embodiments of methods of forming films are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation.

1. A method of forming a layer, the method comprising:
providing a feedstock, the feedstock comprising a first component and a second component;
ionizing at least part of the feedstock thereby forming a plasma,
wherein the plasma comprises constituents selected from: the first component, derivatives of the first component, ions of the first component, ions of derivatives of the first component, the second component, derivatives of the second component, ions of the second component, ions of derivatives of the second component, or combinations thereof, and
wherein the individual identities, individual ratios, total quantities, or any combination thereof of the first and second component in the feedstock can modulate the makeup of the plasma;
forming a beam from the plasma; and
forming a layer from the beam,
wherein the layer includes at least some portion of at least the first or the second component.

2. The method of claim 1, wherein the first component comprises CO, CO₂, or a hydrocarbon.

3. The method of claim 1, wherein the first component comprises acetylene (C₂H₂), methane (CH₄), methylacetylene (C₃H₄), ethylacetylene (C₄H₆), or dimethylacetylene (C₄H₆).

4. The method of claim 1, wherein the first component is from about 99.9% to about 80% of the mass flow of the total mass flow of the feedstock.

5. The method of claim 1, wherein the second component comprises a noble gas, nitrogen (N₂), oxygen (O₂), a hydrocarbon, hydrogen (H₂), or combinations thereof.

6. The method of claim 1, wherein the second component comprises a noble gas.

7. The method of claim 1, wherein the second component comprises argon (Ar), helium (He), neon (Ne), argon (Ar), krypton (Kr), xenon (Xe), or combinations thereof.

8. The method of claim 1, wherein the beam is mass selected.

9. The method of claim 1, wherein the first and second component of the feedstock are introduced differently to a system in which the method is carried out.

10. A method of forming a layer, the method comprising:
providing a feedstock, the feedstock comprising a first component and a second component, and wherein the first component is from about 99.9% to about 80% of the mass flow of the total mass flow of the feedstock;
ionizing at least part of the feedstock thereby forming a plasma,
wherein the plasma comprises constituents selected from: the first component, derivatives of the first component, ions of the first component, ions of derivatives of the first component, the second component, derivatives of the second component, ions of the second component, ions of derivatives of the second component, or combinations thereof, and
wherein the individual identities, individual ratios, total quantities, or any combination thereof of the first and second component in the feedstock can modulate the makeup of the plasma;
forming a beam from the plasma; and
forming a layer from the beam,
wherein the layer includes at least some portion of at least the first or the second component.

11. The method of claim 10, wherein the first component is from about 99.9% to about 90% of the mass flow of the total mass flow of the feedstock.

12. The method of claim 10, wherein the second component comprises a noble gas, nitrogen (N₂), oxygen (O₂), a hydrocarbon, hydrogen (H₂), or combinations thereof.

13. The method of claim 10, wherein the second component comprises a noble gas.

14. The method of claim 10, wherein the second component comprises argon (Ar), helium (He), neon (Ne), argon (Ar), krypton (Kr), xenon (Xe), or combinations thereof.

15. The method of claim 10, wherein the first and second component of the feedstock are introduced differently to a system in which the method is carried out.

16. A method of forming a layer, the method comprising:
providing a feedstock, the feedstock comprising a first component and a second component,
wherein the first component is from about 99.9% to about 80% of the mass flow of the total mass flow of the feedstock, and
wherein the second component is selected from noble gases, nitrogen (N₂), oxygen (O₂), hydrocarbons, hydrogen (H₂), or combinations thereof;
ionizing at least part of the feedstock thereby forming a plasma,
wherein the plasma comprises constituents selected from: the first component, derivatives of the first component, ions of the first component, ions of derivatives of the first component, the second component, derivatives of the second component, ions of the second component, ions of derivatives of the second component, or combinations thereof, and
wherein the individual identities, individual ratios, total quantities, or any combination thereof of the first and second component in the feedstock can modulate the makeup of the plasma;
forming a beam from the plasma; and
forming a layer from the beam,
wherein the layer includes at least some portion of at least the first or the second component.

17. The method of claim 16, wherein the step of ionizing at least part of the feedstock utilizes inductively coupled RF electric fields, capacitively-coupled RF electric fields, ultra high frequency (UHF) electric fields, or electron cyclotron resonance effects in conjunction with various magnetic field configurations.

18. The method of claim 16, wherein the first component is from about 99.9% to about 90% of the mass flow of the total mass flow of the feedstock.

19. The method of claim 16, wherein the second component comprises a noble gas.

20. The method of claim 10, wherein the second component comprises argon (Ar), helium (He), neon (Ne), argon (Ar), krypton (Kr), xenon (Xe), or combinations thereof.
